(19) United States
(12) Patent Application Publication
(10) Pub. No.: US 2013/0075135 A1
(43) Pub. Date: Mar. 28, 2013

(54) PRINTED CIRCUIT BOARD AND MANUFACTURING METHOD THEREOF

(71) Applicant: Jee-Soo MOK, Gyeonggi-do (KR)

(72) Inventor: Jee-Soo MOK, Gyeonggi-do (KR)

(21) Appl. No.: 13/627,254

(22) Filed: Sep. 26, 2012

(30) Foreign Application Priority Data
Sep. 26, 2011 (KR) 10-2011-0097079

(51) Int. Cl. H05K 1/00; H05K 3/00

(52) U.S. Cl. 174/250; 427/8

(57) ABSTRACT

A printed circuit board and a method of manufacturing the same are disclosed. An embodiment of the present invention provides a printed circuit board in which a plurality of printing areas are formed, wherein a plurality of alignment marks are formed in each of the printing areas.

### CROSS-REFERENCE TO RELATED APPLICATIONS

This application claims the benefit of Korean Patent Application No. 10-2011-0097079, filed with the Korean Intellectual Property Office on Sep. 26, 2011, the disclosure of which is incorporated herein by reference in its entirety.

### BACKGROUND

1. Technical Field

The present invention relates to a printed circuit board and a manufacturing method thereof that can improve conformability in a solder resist process.

2. Background Art

Electronic devices are increasingly concentrated and performing better. Electronic parts are becoming increasingly smaller, more integrated and faster. In line with this trend, printed circuit boards are also becoming thinner and lighter and wired in a more concentrated pattern.

The wiring pattern of a wiring board can be covered by a solder resist, which can be highly concentrated in order to cover the wiring pattern. It is required that the solder resist match with the wiring pattern precisely.

The wiring board can have alignment marks formed therein so as to precisely align the solder resist to the wiring pattern of a printing area. The printing area of the wiring board can have a solder resist layer formed therein. As the solder resist layer is exposed so as to correspond to data modified by the alignment marks, a solder resist pattern can be formed. As the wiring pattern becomes finder and more concentrated, it is increasingly required that the solder resist pattern be finer and more concentrated.

Korean Patent Publication 2006-0106094 discloses an exposure method by a direct imaging exposure apparatus. An alignment mark is formed on a board, and a relative position of the board and an exposure head is aligned using the alignment mark before exposing the board.

### SUMMARY

The present invention provides a printed circuit board and a method of manufacturing the printed circuit board that can improve conformability per location of a wiring board in an exposure process.

An aspect of the present invention features a printed circuit board having a plurality of printing areas formed therein, each of the printing areas having a plurality of alignment marks formed therein.

The alignment marks can be arranged in a circumference inside or outside a boundary of each of the printing areas.

Each of the printing areas can have six or more alignment marks formed therein.

The six or more alignment marks can be formed at corners of either side as well as middle portions of the printing areas.

The alignment marks can be arranged in plural lines in an X-axis direction and a Y-axis direction in each of the printing areas.

Another aspect of the present invention features a method of manufacturing a printed circuit board that includes: forming a plurality of printing areas on a metal film of a wiring board and forming a plurality of alignment marks in each of the printing areas; forming a solder resist layer on the wiring board; generating measurement data by reading a wiring pattern; computing an error by comparing coordinates of the measurement data with coordinates of reference data; generating corrected data by correcting the reference date so as to correspond to the error; and forming a solder resist pattern by exposing the wiring board so as to correspond to the corrected data.

In the step of forming a plurality of alignment marks, the alignment marks can be arranged in a circumference inside or outside a boundary of each of the printing areas.

In the step of forming a plurality of alignment marks, each of the printing areas can have six or more alignment marks formed therein.

The six or more alignment marks can be formed at corners of either side as well as middle portions of the printing areas.

The alignment marks can be arranged in plural lines in an X-axis direction and a Y-axis direction in each of the printing areas.

### BRIEF DESCRIPTION OF THE DRAWINGS

FIG. 1 is a plan view illustrating a printed circuit board in accordance with a first embodiment of the present invention.

FIGS. 2 and 3 show printing areas deformed in a printed circuit board.

FIG. 4 is a plan view illustrating a printed circuit board in accordance with a second embodiment of the present invention.

FIG. 5 is a flow diagram illustrating a method of manufacturing a printed circuit board in accordance with an embodiment of the present invention.

### DETAILED DESCRIPTION

Since there can be a variety of permutations and embodiments of the present invention, certain embodiments will be illustrated and described with reference to the accompanying drawings. This, however, is by no means to restrict the present invention to certain embodiments, and shall be construed as including all permutations, equivalents and substitutes covered by the ideas and scope of the present invention. Throughout the description of the present invention, when describing a certain technology is determined to evade the point of the present invention, the pertinent detailed description will be omitted.

Hereinafter, a printed circuit board in accordance with a first embodiment of the present invention will be described with reference to the accompanying drawings.

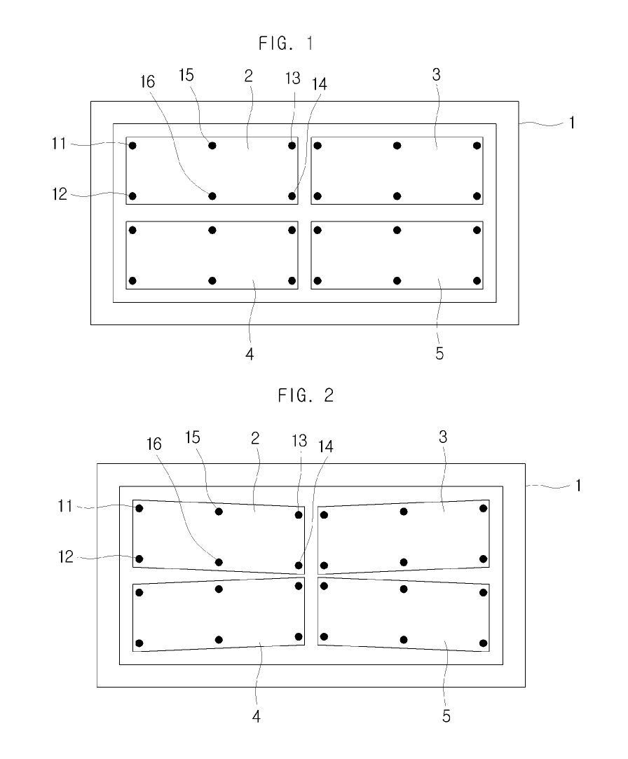

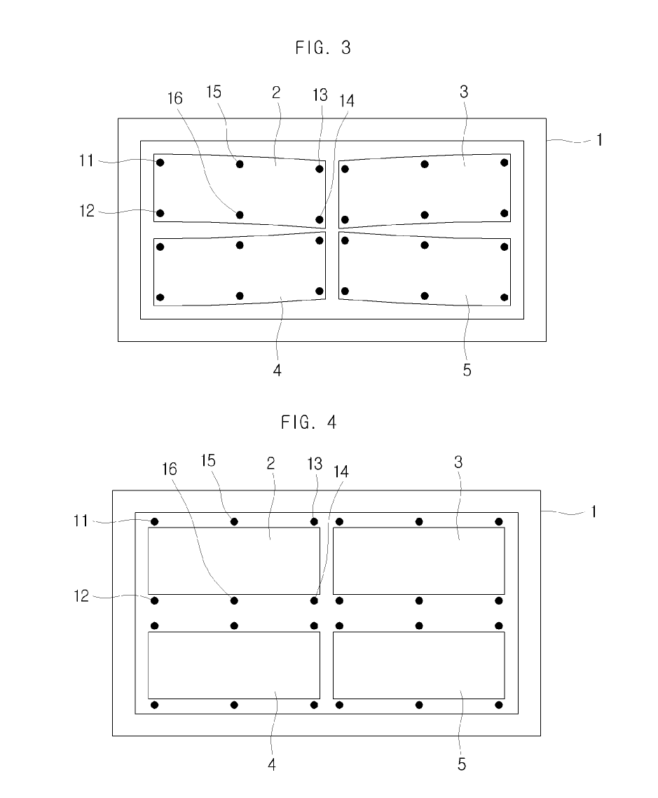

FIG. 1 is a plan view illustrating a printed circuit board in accordance with a first embodiment of the present invention, and FIGS. 2 and 3 show printing areas deformed in a printed circuit board.

Referring to FIG. 1, a metal layer can be formed on an insulator, which can be formed by impregnating epoxy resin in polyimide nonwoven fabric. The metal layer can be copper foil. The metal layer can be formed on one surface or both surfaces of the insulator.

A wiring pattern can be formed on a wiring board 1 by etching the metal layer. The wiring pattern can be formed in a plurality of printing areas 2, 3, 4, 5. The wiring board 1 can have the plurality of printing areas 2, 3, 4, 5 formed on a surface thereof. The printing areas 2, 3, 4, 5 can be arranged at regular intervals. Although FIG. 1 illustrates that four printing areas 2, 3, 4, 5 are formed on the wiring board 1, the number of printing areas are not restricted to what is described and illustrated herein.

Each of the printing areas 2, 3, 4, 5 can have a plurality of alignment marks 11-16. Since the plurality of alignment marks 11-16 are formed in each of the printing areas 2, 3, 4, 5 on the wiring board 1, it is possible to measure conformity error for each of the printing areas 2, 3, 4, 5 even if deformation or misalignment occurs in each of the printing areas 2, 3, 4, 5 on the wiring board 1. Accordingly, it becomes possible to modify the conformity error for each of the printing areas 2, 3, 4, 5 and expose the wiring board 1 to have a solder resist pattern match with the wiring pattern.

The alignment marks 11-16 can be formed in various shapes, such as dots, squares, crosses, etc. The alignment marks 11-16 can be simultaneously formed when the wiring pattern is formed in the printing areas 2, 3, 4, 5. These alignment marks 11-16 can function as reference points for aligning the positions of the printing areas 2, 3, 4, 5 when a solder resist layer is exposed in order to form the solder resist pattern.

The alignment marks 11-16 can be arranged along a circumference inside a boundary of each of the printing areas 2, 3, 4, 5. Since the alignment marks 11-16 are arranged along the circumference inside the boundary of each of the printing areas 2, 3, 4, 5, it is possible to accurately determine to which overall shape the printing area 2, 3, 4, 5 is deformed.

Each of the printing areas 2, 3, 4, 5 can have six or more alignment marks 11-16 formed therein. Here, the six or more alignment marks 11-16 can be formed at corners of either side as well as middle portions of the printing areas 2, 3, 4, 5.

For example, the alignment marks 11-14 can be each formed at every corner of each of the printing areas 2, 3, 4, 5, and two alignment marks 15, 16 can be each formed on an upper side and a lower side of the middle portions of the printing areas 2, 3, 4, 5. Since it is possible to reduce the distance between the alignment marks and increase the number of the alignment marks in each of the printing areas 2, 3, 4, 5, coordinates to which the alignment marks of the printing areas 2, 3, 4, 5 are deformed or shifted can be precisely measured.

Moreover, in the case that the printing areas 2, 3, 4, 5 are rotationally deformed as shown in FIG. 2, the deformed coordinates can be accurately measured. If four alignment marks were each formed at every corner of each of the printing areas 2, 3, 4, 5, it would be difficult to measure the deformed coordinates of the printing areas 2, 3, 4, 5 accurately because the rates by which the alignment marks are shifted would be different from one another in each of the printing areas 2, 3, 4, 5.

The alignment marks 11-16 can be arranged in plural lines in an X-axis direction (longitudinal direction) and a Y-axis direction (latitudinal direction) in each of the printing areas 2, 3, 4, 5. For example, in the case that six alignment marks are formed in each printing area, there can be two lines of alignment marks arranged in the X-axis direction and three lines of alignment marks in the Y-axis direction.

The wiring board 1 can have the solder resist layer formed on an upper surface thereof. The solder resist layer can be exposed in an exposure apparatus to form the solder resist pattern.

Meanwhile, measurement changes can occur in the wiring board 1 until the solder resist pattern is formed after the wiring pattern is formed. That is, as the wiring board 1 has different contraction rates and expansion rates depending on the location, the relative positions of the printing areas 2, 3, 4, 5 that are arranged in a same pitch on the wiring board 1 may be changed. Once the relative positions are changed, the pitches between the printing areas 2, 3, 4, 5 can be changed.

For instance, the wiring board 1 can have portions where the metal layer occupies a wider area and portions where the metal layer occupies a smaller area, and thus the contraction rate and the expansion rate can be different depending on the location of the wiring board 1. Accordingly, warpage or deformation can be different depending on the location of the wiring board 1.

Moreover, the wiring board 1 can be cooled down faster at a perimeter and slower at a center portion. As the cooling speed is different depending on the location of the wiring board 1, the printing areas 2, 3, 4, 5 can be shifted or deformed. Accordingly, it is possible that the printing areas 2, 3, 4, 5 are shifted or bent to positions that are different from one another.

Referring to FIG. 2, the printing areas 2, 3, 4, 5 of the wiring board 1 can be deformed to be slanted toward the center portion of the wiring board 1. For example, the alignment marks 15, 16 located at the middle portion of the printing area can be slightly shifted toward the center portion of the wiring board 1, and the alignment marks 13, 14 located at the corners closer to the center portion of the wiring board 1 can be shifted more than the alignment marks 15, 16 of the middle portion. Here, the shifted distance of the alignment marks 13, 14 of the corners closer to the center portion of the wiring board 1 can be twice as much as the shifted distance of the alignment marks 15, 16 of the middle portion, relative to the positions of the alignment marks 11, 12 that are closer to an edge of the wiring board 1. Accordingly, referring to the printing area 2 only, the alignment marks 11, 13, 15 located on a top line and the alignment marks 12, 14, 16 located on a bottom line can be shifted to be slanted in parallel.

By measuring the slanted alignment marks 11-16 and calculating coordinates of reference data, an error between the slanted printing areas 2, 3, 4, 5 and the coordinates of the reference data can be readily computed. Here, since the distances between the alignment marks are narrower in each of the printing areas, it is possible to calculate the error of the coordinates relatively more accurately and precisely.

Referring to FIG. 3, the printing areas 2, 3, 4, 5 of the wiring board 1 can be deformed to be slightly bent. Here, relative to the alignment marks 11, 12 on one side, the shifted distance of the alignment marks 13, 14 located at the corners of the other side can be different from the shifted distance of the alignment marks 15, 16 located at the middle portion. However, since it is possible to assess the rate between the alignment marks 15, 16 located at the middle portion and the alignment marks 13, 14 located on the other side, an error of coordinates of reference data can be accurately calculated. Moreover, the narrower the distances between the alignment marks 11-16 are, the more accurately the error of the coordinates of the reference data can be calculated. In addition, since it is possible to reduce the distances between the alignment marks and increase the number of alignment marks in each of the printing areas 2, 3, 4, 5, a rotated coordinates of the printing areas 2, 3, 4, 5 can be accurately measured.

As it is possible with the present invention to form a plurality of alignment marks 11-16 in each of the printing areas 2, 3, 4, 5 of the wiring board 1 and measure the deformation of the wiring pattern for each of the printing areas 2, 3, 4, 5, the solder resist layer can be exposed to correspond to the wiring pattern to form the solder resist pattern.

FIG. 4 is a plan view illustrating a printed circuit board in accordance with a second embodiment of the present invention.

Referring to FIG. 4, the alignment marks 11-16 can be arranged at a periphery outside a boundary of each of the printing areas 2, 3, 4, 5. Such alignment marks 11-16 are substantially the same as the alignment marks 11-16 illustrated in FIG. 1 in their configurations, except for the arrangement at the periphery outside the boundary of the printing areas 11-16. However, as the alignment marks 11-16 are arranged outside the printing areas 2, 3, 4, 5, areas for forming the wiring pattern can be relatively larger in the printing areas 2, 3, 4, 5.

Hereinafter, a method of manufacturing the above-described printed circuit board will be described.

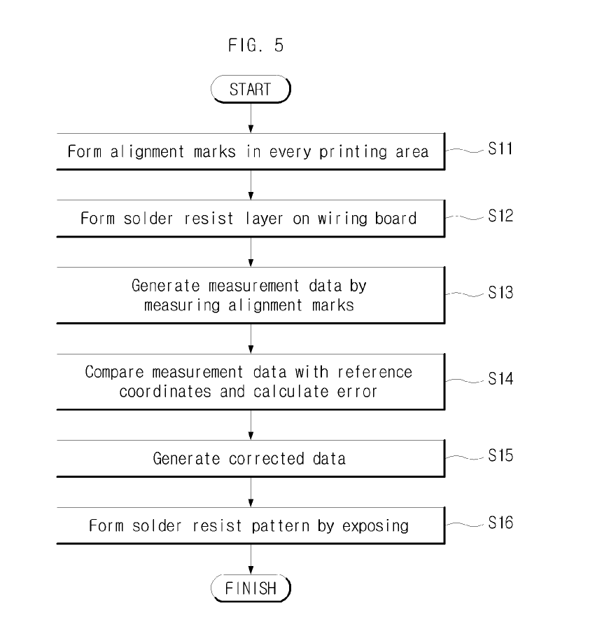

FIG. 5 is a flow diagram illustrating a method of manufacturing a printed circuit board in accordance with an embodiment of the present invention.

Referring to FIG. 5, in S11, a plurality of printing areas 2, 3, 4, 5 are formed on a metal film of the wiring board 1, and a plurality of alignment marks 11-16 are formed in each of the printing areas 2, 3, 4, 5. The wiring pattern and the alignment marks 11-16 of the printing areas 2, 3, 4, 5 can be formed at the same time. In step S12, the solder resist layer is formed on the wiring board 1.

The wiring board 1 can be transported to an exposure apparatus (not shown) by a transportation apparatus. The wiring board 1 can be arranged at an exposure location in the exposure apparatus.

A CCD camera of the exposure apparatus can scan an image of the wiring board 1. By reading the image of the wiring pattern, coordinates for the alignment marks 11-16 can be obtained for every printing area 2, 3, 4, 5. Then, based on the coordinates of the alignment marks 11-16 for each of the printing areas 2, 3, 4, 5, measurement data can be generated (S13).

Reference data of the wiring board 1 is pre-stored in a controller. Configured in the reference data are coordinates for the alignment marks 11-16 of every printing area 2, 3, 4, 5 and coordinates for the wiring pattern having a relative positional relation based on the coordinates of the alignment marks 11-16.

In S14, the controller calculates an error by comparing the coordinates of the alignment marks 11-16 for each of the printing areas 2, 3, 4, 5 in the measurement data with the coordinates of the alignment marks 11-16 for each of the printing areas 2, 3, 4, 5 in the reference data.

In S15, the controller generates corrected data by correcting the coordinates of the reference data so as to correspond to the error. Here, the coordinates for the alignment marks 11-16 of the reference data can be shifted by as much as the error, and the coordinates for the wiring pattern can be shifted in an appropriate ratio according to a displacement by which the alignment marks 11-16 are shifted.

The corrected data is displacement of the coordinates that corresponds to an overall outline of the deformed printing areas 2, 3, 4, 5 and to a positional change of the wiring pattern. Accordingly, as a plurality of alignment marks 11-16 are formed in each of the printing areas 2, 3, 4, 5, position correction becomes possible by assessing minute deformation errors for each of the printing areas 2, 3, 4, 5. Furthermore, it is possible to correct not only the overall displacement of the deformed printing areas 2, 3, 4, 5 but also minute displacement of the wiring pattern. Moreover, since the distances between the alignment marks 11-16 are narrow, the displacement of the coordinates can be corrected more precisely. Therefore, the conformity of the wiring pattern and the solder resist can be substantially more precise.

In the case that each of the printing areas 2, 3, 4, 5 has six or more alignment marks formed therein, it is possible to accurately measure not only the error from shifted coordinates but also the error from rotated coordinates of the printed areas. Accordingly, the conformity of the wiring pattern and the solder resist can be precisely achieved.

In S16, the exposure apparatus exposes the solder resist layer. Here, the solder resist layer can be exposed to UV light by a digital mirror method. The UV light can photopolymerize portions where the wiring pattern is formed. By developing the exposed solder resist layer, the solder resist pattern is formed. Here, the wiring pattern and the solder resist pattern can be precisely matched with each other.

While the present invention has been described with reference to certain embodiments, the embodiments are for illustrative purposes only and shall not limit the invention. It is to be appreciated that those skilled in the art can change or modify the embodiments without departing from the scope and spirit of the invention. It shall be also appreciated that a very large number of embodiments other than those described herein are possible within the scope of the present invention, which shall be defined by the claims appended below.

What is claimed is:

1. A printed circuit board having a plurality of printing areas formed therein, each of the printing areas having a plurality of alignment marks formed therein.

2. The printed circuit board of claim 1, wherein the alignment marks are arranged in a circumference inside or outside a boundary of each of the printing areas.

3. The printed circuit board of claim 1, wherein each of the printing areas has six or more alignment marks formed therein.

4. The printed circuit board of claim 3, wherein the six or more alignment marks are formed at corners of either side as well as middle portions of the printing areas.

5. The printed circuit board of claim 1 or 4, wherein the alignment marks are arranged in plural lines in an X-axis direction and a Y-axis direction in each of the printing areas.

6. A method of manufacturing a printed circuit board, the method comprising:
forming a plurality of printing areas on a metal film of a wiring board and forming a plurality of alignment marks in each of the printing areas;
forming a solder resist layer on the wiring board;
generating measurement data by reading a wiring pattern;
computing an error by comparing coordinates of the measurement data with coordinates of reference data;
generating corrected data by correcting the reference date so as to correspond to the error; and
forming a solder resist pattern by exposing the wiring board so as to correspond to the corrected data.

7. The method of claim 6, wherein, in the step of forming a plurality of alignment marks, the alignment marks are arranged in a circumference inside or outside a boundary of each of the printing areas.

8. The method of claim 6, wherein, in the step of forming a plurality of alignment marks, each of the printing areas has six or more alignment marks formed therein.

9. The method of claim 8, wherein the six or more alignment marks are formed at corners of either side as well as middle portions of the printing areas.

10. The method of claim 6 or 9, wherein the alignment marks are arranged in plural lines in an X-axis direction and a Y-axis direction in each of the printing areas.
